(19) United States
(12) Patent Application Publication
(10) Pub. No.: US 2007/0206419 A1
(43) Pub. Date: Sep. 6, 2007

(54) NONVOLATILE SEMICONDUCTOR MEMORY DEVICE

(75) Inventor: Eiichi Makino, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/682,564

(22) Filed: Mar. 6, 2007

(30) Foreign Application Priority Data
Mar. 6, 2006 (JP) 2006-060309

(51) Int. Cl. G11C 5/02; G11C 16/04; G11C 5/06; G11C 11/34

(52) U.S. Cl. 365/185.11; 365/63; 365/51

(57) ABSTRACT

A nonvolatile semiconductor memory device having a first memory cell array including a plurality of electrically reprogrammable and erasable nonvolatile memory cells formed in a first area of a semiconductor substrate, a second memory cell array including a plurality of electrically reprogrammable and erasable nonvolatile memory cells formed in second area different from said first area of said semiconductor substrate, said first and second memory cell arrays being arranged in a first direction, a first page buffer block for storing data from said first memory cell array, said first page buffer block being arranged in said first memory cell array along a first direction, a second page buffer block for storing data from said second memory cell array, said second page buffer block being arranged in said second memory cell array along said first direction, a pad section for inputting data to and outputting data from said first memory cell array and said second memory cell array, said pad section having a plurality of pads arranged in an end of a semiconductor chip along a second direction perpendicular to said first direction, a first data line for supplying data from said first memory cell array to said pad section, said first data line being arranged in said first memory cell array along said first direction and a second data line for supplying data from said second memory cell array to said pad section, said second data line being arranged in said second memory cell array along said first direction over said first page buffer block.

### CROSS-REFERENCE OF RELATED APPLICATIONS

This application is based on and claims the benefit of priority from the prior Japanese Patent Application No. 2006-060309, filed on Mar. 6, 2006, the entire contents of which are incorporated herein by reference.

### TECHNICAL FIELD

The present invention relates to the layout of a nonvolatile semiconductor memory device.

### BACKGROUND OF THE INVENTION

Conventionally, EEPROM in which data can be electrically reprogrammable has been known as one of semiconductor memory devices. A NAND-type EEPROM (NAND-type flash memory) in particular in which a plurality of memory cells based on a unit for storing one bit are connected in series has a high reprogramming speed and is suitable for a higher capacity. Thus, a NAND-type EEPROM has been increasingly required as a data memory device for a small memory card and a mobile information terminal for example.

In recent years, there has been an increasing demand for a higher memory capacity, a higher data processing speed, and higher integration as well as a thinner package size and a smaller size.

Conventionally, various methods for realizing a high-speed reading in a nonvolatile semiconductor memory device have been looked for. Another method for reducing an area occupied by a semiconductor element and a wiring placed on a chip has been looked for. A nonvolatile semiconductor memory devices described above are described in Japanese Patent Publications Nos. 2003-338185 and 2004-280867.

### SUMMARY OF THE INVENTION

According to one embodiment of the present invention, a nonvolatile semiconductor memory device including:

a first memory cell array including a plurality of electrically reprogrammable and erasable nonvolatile memory cells formed in a first area of a semiconductor substrate;

a second memory cell array including a plurality of electrically reprogrammable and erasable nonvolatile memory cells formed in second area different from said first area of said semiconductor substrate, said first and second memory cell arrays being arranged in a first direction;

a first page buffer block for storing data from said first memory cell array, said first page buffer block being arranged in said first memory cell array along a first direction;

a second page buffer block for storing data from said second memory cell array, said second page buffer block being arranged in said second memory cell array along said first direction;

a pad section for inputting data to and outputting data from said first memory cell array and said second memory cell array, said pad section having a plurality of pads arranged in an end of a semiconductor chip along a second direction perpendicular to said first direction;

a first data line for supplying data from said first memory cell array to said pad section, said first data line being arranged in said first memory cell array along said first direction; and

a second data line for supplying data from said second memory cell array to said pad section, said second data line being arranged in said second memory cell array along said first direction over said first page buffer block.

According to one embodiment of the present invention, a nonvolatile semiconductor memory device including:

a first memory cell array including a plurality of electrically reprogrammable and erasable nonvolatile memory cells formed in a first area of a semiconductor substrate;

a second memory cell array including a plurality of electrically reprogrammable and erasable nonvolatile memory cells formed in second area different from said first area of said semiconductor substrate, said first and second memory cell arrays being arranged in a first direction;

a first page buffer block for storing data from said first memory cell array, said first page buffer block being arranged in said first memory cell array along a first direction;

a second page buffer block for storing data from said second memory cell array, said second page buffer block being arranged in said second memory cell array along said first direction;

a pad section for inputting data to and outputting data from said first memory cell array and said second memory cell array, said pad section having a plurality of pads arranged in an end of a semiconductor chip along a second direction perpendicular to said first direction;

a first peripheral circuit including data collect circuit for collecting data from said first and second page buffer blocks and outputting collected data to said pad section, said first peripheral circuit being arranged between said first memory cell array and said second memory cell array along said second direction;

a second peripheral circuit including a control circuit arranged between said first memory cell array and said pad section along said second direction; and

a data line for supplying data from said data collect circuit to said second peripheral circuit and said pad section, said data line being arranged in said first memory cell array along said first direction over said first page buffer block.

According to one embodiment of the present invention, a semiconductor device including:

a plurality of nonvolatile semiconductor memory devices according to claim 1 or claim 13, said plurality of nonvolatile semiconductor memory devices being stacked and being electrically connected via a through hole wiring formed in respective semiconductor substrates of said plurality of nonvolatile semiconductor memory devices.

### BRIEF DESCRIPTION OF THE DRAWINGS

FIG. 1 is an example of functional block diagram of a NAND-type flash memory.

FIG. 2 is an example of circuit diagram illustrating the structure of a memory cell array in the flash memory.

FIG. 3 is an example of floor plan of the flash memory.

FIG. 4 is an example of another floor plan of the flash memory.

FIG. 5 is an example of floor plan of the flash memory according to first embodiment of the present invention.

FIG. 6 is an example of floor plan illustrating the flash memory according to first embodiment of the present invention having the same structure as that of FIG. 5 and using shared sense amplifiers.

FIG. 7 shows the same structure as that of FIG. 5 and shows an example of data line of a page buffer block far away from a pad section placed at a chip end of a semiconductor wiring that is wired while bypassing a memory cell array.

FIG. 8 is an example of floor plan illustrating the flash memory according to second embodiment of the present invention.

FIG. 9 is an example of floor plan of the flash memory according to second embodiment of the present invention having the same structure as that of FIG. 8 in which a data line is shared by left and right planes.

FIG. 10 is an example of floor plan of the flash memory according to second embodiment of the present invention having the same structure as that of FIG. 8 and using shared sense amplifiers.

FIG. 11 is an example of floor plan of the flash memory according to third embodiment of the present invention.

FIG. 12 is an example of floor plan of the flash memory according to second embodiment of the present invention having the same structure as that of FIG. 8 and using shared sense amplifiers.

FIG. 13 shows an example of multilayer structure of a NAND-type flash memory according to fourth embodiment using System in Package (Sip).

### DETAILED DESCRIPTION OF THE INVENTION

Hereinafter, embodiments of a nonvolatile semiconductor memory device according to the present invention will be described with reference to the drawings. It is noted that embodiments shown below are mere examples of desirable embodiments of a nonvolatile semiconductor memory device of the present invention. The present invention can be carried out in many other embodiments and are not construed as being limited to the contents of embodiments shown below.

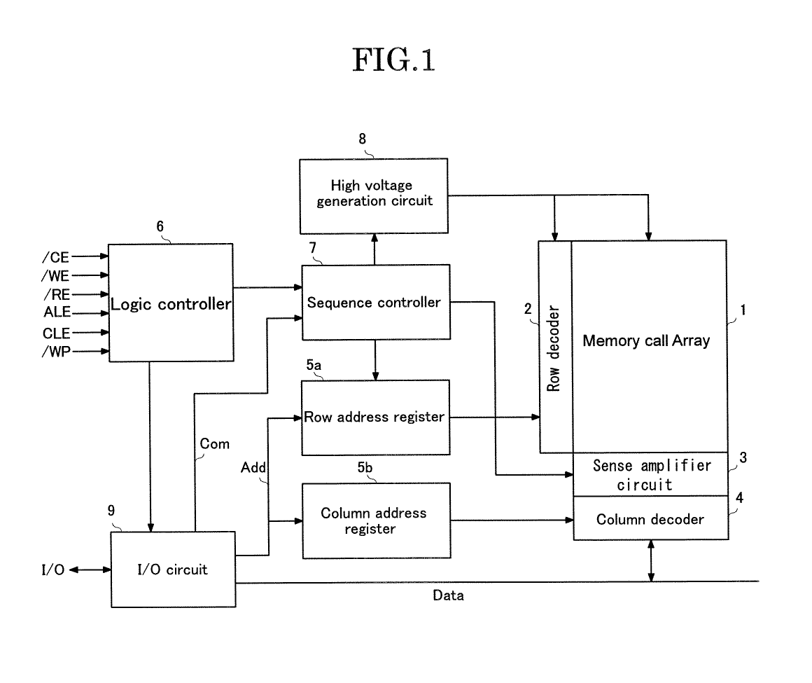

First, the entire structure and function of a NAND-type flash memory will be described. FIG. 1 is an example of a functional block diagram illustrating a NAND-type flash memory. A memory cell array 1 is structured by arranging a plurality of floating gate-type memory cells in a matrix manner. A row decoder (including a word line driver) 2 selects a block selection in the memory cell array 1 and selects and drives the selection of a word line and a selection gate line. A sense amplifier circuit 3 includes sense amplifiers for one page for amplifying bit line data of the memory cell array 1 to a logic level required for the next processing. The sense amplifier circuit may be included in a page buffer which temporarily stores data from the memory cell array.

Read data for one page is selected by a column decoder (column gate) 4 and is output via an I/O circuit 9 to an external I/O terminal. The external I/O terminal is connected with an error correction circuit (not shown) for example. The error correction circuit also may be provided in a chip. Program data supplied from the I/O terminal is given via the I/O circuit 9 to the column decoder 4 and is loaded to the sense amplifier circuit 3 by selecting by the column decoder 4. An address signal Add is input via the I/O circuit 9 and row and column addresses are transferred to a row address register 5a and a column address register 5b, respectively.

A logic controller 6 outputs internal timing signals of reading, programming, and erasing operations based on a control signal such as a programming enable signal /WE, a reading enable signal /RE, an address latch enable signal ALE, or a command latch enable signal CLE. A sequence controller 7 performs, based on these timing signals, sequence control of data programming and erasing operations and control of data reading operation. A high voltage generation circuit 8 is controlled by the sequence controller 7 and generates various high voltages used for data programming and erasing operations. These controllers 6 and 7 and high voltage generation circuit 8 constitute a control means.

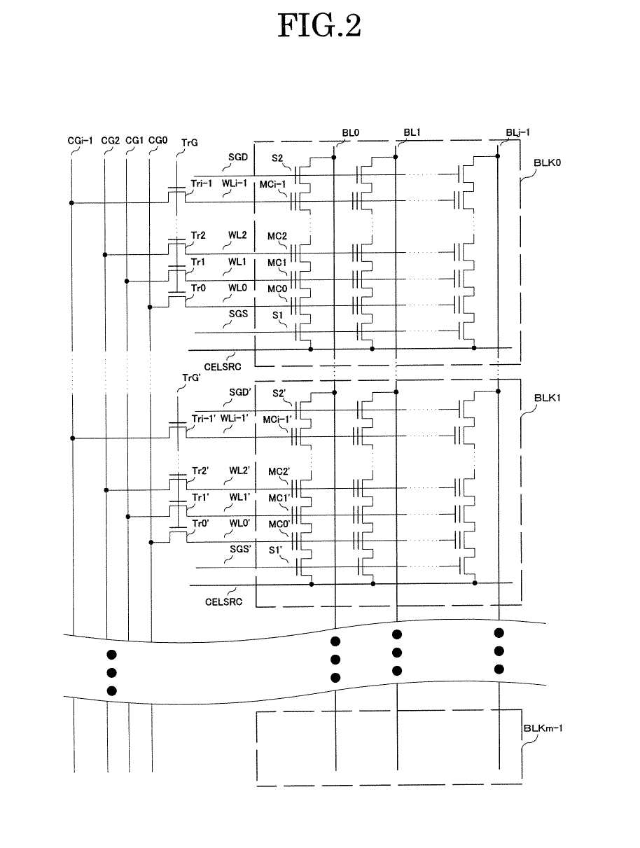

On an actual semiconductor chip, the memory cell array 1 includes of a plurality of cell array blocks that are physically independent from one another. FIG. 2 shows an example where one cell array is composed of “m” cell array blocks BLKk (k=0 to m−1). One substrate has thereon a plurality of blocks. A collection of blocks arranged on one substrate is handled as one plane. Each cell array block BLKk has a plurality of word lines WL0 to WLi−1 and bit lines BL0 to BL1 intersecting to one another. Bit lines BL0 to BLj−1 are arranged over all cell array blocks BLKk. Intersections of the respective word lines WL0 to WLi−1 and bit lines BL0 to BLj−1 have memory cells MC0, 0 to MCi−1, and j−1. Intersections of one bit line BL0 and WL0 to WLi−1 in one block BLK0 have a plurality of floating gate-type memory cells MC0 to MCi−1 respectively that are connected in serial to constitute a cell string. A selection gate transistor S1 is inserted between a source of one end-side cell of a cell string and a common source line CELSRC. A selection gate transistor S2 is inserted between a drain of the other end-side cell of the cell string and a bit line BL. One cell string and two selection transistors connected to both ends thereof constitute a NAND cell unit.

The respective memory cells MC0 to MCi−1 have control gates connected to word lines WL0 to Wli−1 respectively. Selection gate transistors S1 and S2 have selection gates connected to selection gate lines SGS and SGD respectively that are provided in parallel with the word line WL, respectively. A collection of a plurality of memory cells MC along one word line WL constitutes one page as a unit of data reading and programming operations.

Next, a physical layout on a semiconductor chip of a NAND-type flash memory (floor plan) will be described. In the following description, a block including a plurality of page buffers including a connection with a bit line, a bit line switching switch, a precharge circuit, a sense amplifier circuit, and a data retention (latch) circuit respectively is called as a page buffer block. In the following description of the layouts of the drawings, left and right directions will be called an X direction or simply X and upper and lower directions will be called a Y direction or simply Y.

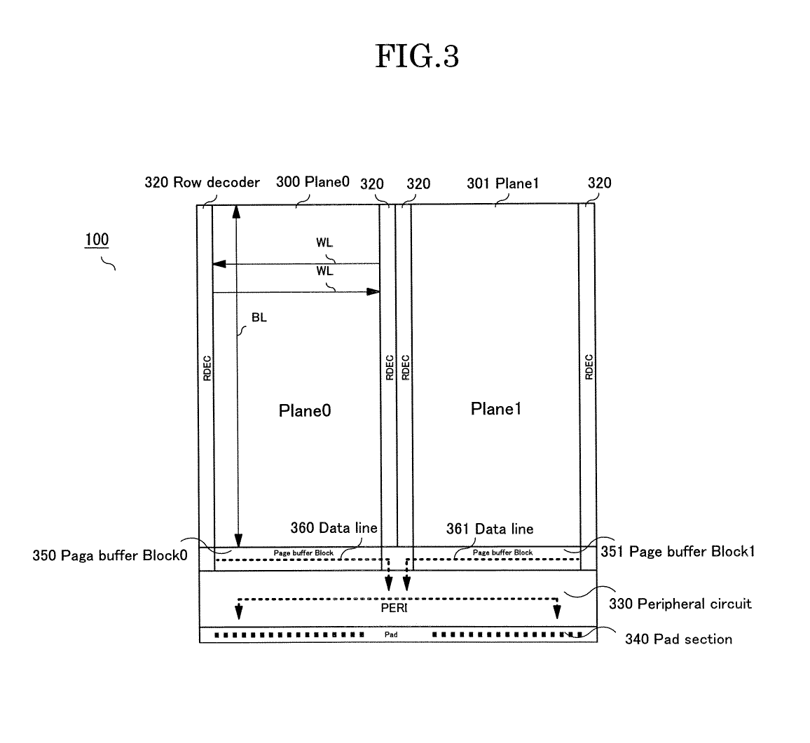

FIG. 3 illustrates a physical layout (floor plan) on a chip of a NAND-type flash memory. One plane means a unit of one memory cell array. Two plane 300 and plane 301 are placed in the X direction on a semiconductor chip 100. The plane 300 is sandwiched between row decoders 320. The plane 301 is also sandwiched between row decoders 320. At the lower side in the Y direction, a page buffer block 350 corresponding to the plane 300 is provided. And a page buffer block 351 corresponding to the plane 301 is provided. At the lower sides of the page buffer blocks 350 and 351, a peripheral circuitry 330 is provided. The peripheral circuitry 330 includes, for example, control circuits such as the logic controller 6, the sequence controller 7, the high voltage generation circuit 8, and the I/O circuit 9 shown in FIG. 1. At an end of the lower side in the Y direction, an arrangement region of a pad section 340 including plural pads connected with an external terminal by wire bonding is provided.

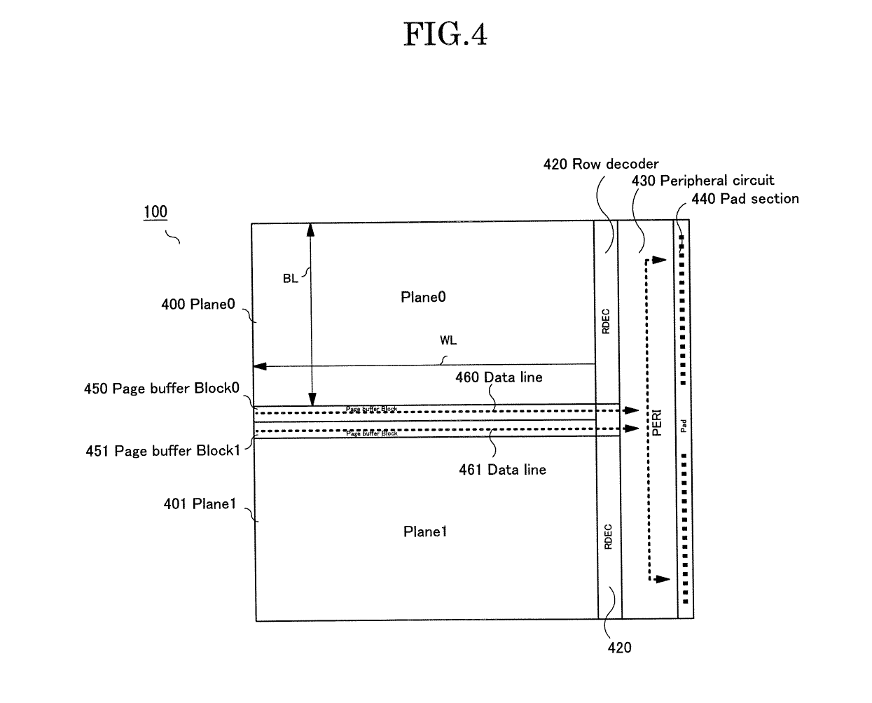

FIG. 4 shows another physical layout (floor plan) on a chip of a NAND-type flash memory. A pad section arrangement region is provided at a right end in the X direction on the semiconductor chip 100. A plane 400 and a plane 401 are provided in an upper and lower direction of the chip in the Y direction. Page buffer blocks 450 and 451 are arranged between the plane 400 and the plane 401. Row decoders 420 are provided at right sides of the planes 400 and 401, respectively. At a further right side of the row decoders 420, a peripheral circuitry 430 is provided. At a right end, an arrangement region of a pad section 440 is provided.

With higher speed and higher integration due to a higher capacity, a microfabrication technique has been sophisticated and thus a wafer process of a NAND-type flash memory has a tendency where a wiring width has been further reduced. However, a wiring specific resistance increases with an increase of a wiring length and with a decrease of a wiring width. Thus, a problem is caused where a RC delay time is increased due to this wiring resistance and a capacity between wirings due to an interlayer insulating film. An increased RC delay time means a contradiction to the demand for a more high-speed data transmission.

When one package includes a plurality of memory cell arrays (planes) every page buffer block may have a different wiring length from a page buffer block to a pad section depending on a pad section arrangement region. In this case, every page buffer block has a different RC delay time, thus causing a problem of skew. The term “skew” herein means the length of a temporal difference among a plurality of events that should be simultaneously generated in order to perform a plurality of data transmission processings. Simultaneous data processings must be performed in accordance with a page buffer block having the longest RC delay time, which is a cause of hindering a more high-speed data transmission.

In the embodiments shown in FIG. 3 and FIG. 4, two planes and two page buffer blocks are shown. Two planes do not require a data line length connecting a pad section to a page buffer block to be long. Two planes also do not cause a problem of skew because data line lengths from two page buffer blocks to a pad section are equal and the same delay time is obtained.

However, when two planes are compared with four planes, a bit line length or a word line length in one plane is longer. The long bit line length or word line length causes an increased specific resistance of the wiring and thus RC delay may be caused. When an area of a semiconductor chip is increased, it's necessary to divide two planes to four planes. A NAND-type flash memory has cell arrays having a cyclic pattern respectively and thus can be miniaturized easily. A wafer process of a NAND-type flash memory also has a tendency where a wiring width has been further reduced. Thus, the number of planes placed on one semiconductor chip will be increased (e.g., four planes, eight planes, or 4×n planes on one semiconductor chip).

When four or more planes are arranged on a semiconductor chip and a pad section arranged on the semiconductor chip end, a data line length from a page buffer block to a pad section is increased. Furthermore, data line lengths from the respective page buffer blocks to the pad section are not equal. Thus, the problem of skew cannot be ignored in some data line wiring methods.

To prevent this, a method may be considered in which a pad section placed at the center of a semiconductor chip to reduce a data line length from a page buffer block to the pad section and to equalize data line lengths from the respective page buffer blocks to the pad section. The pad section placed at the center of a semiconductor chip also causes power lines for supplying power to the respective circuits to be shorter than a case where a pad section is placed at a semiconductor chip end. Thus, the power line width that is ½ shorter than a case where a pad section is placed on a semiconductor chip end can be achieved.

However, the pad section placed at the center of a semiconductor chip causes a long wire bonding length and mass productivity is deteriorated due to a problem in a package technique. When the size of one semiconductor chip is increased, a wire bonding length is further increased and is difficultly realized due to a problem in a package technique. Thus, the present inventor has reached embodiments where even a conventional layout in which a pad section is placed at a semiconductor chip end can place a plurality of planes with the minimum data line length and with the minimum skew.

### Embodiment 1

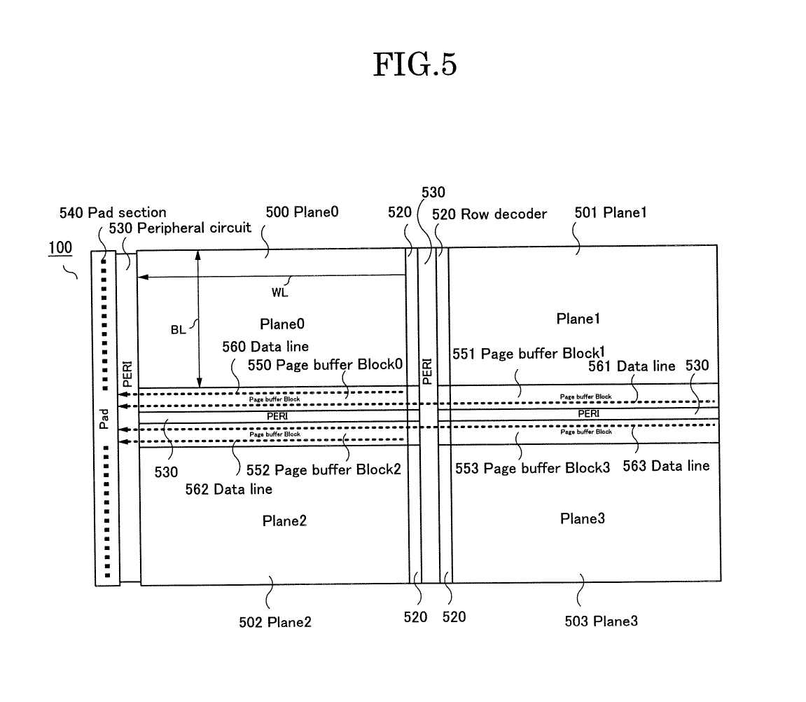

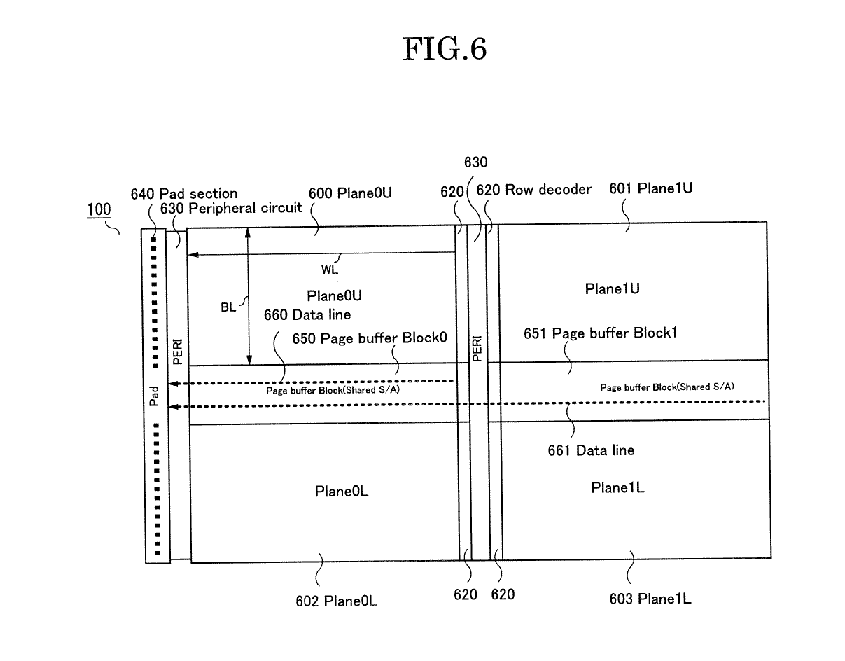

FIG. 5 and FIG. 6 show an example of a NAND-type flash memory as a nonvolatile semiconductor memory device according to Embodiment 1 of the present invention respectively. FIG. 5 is a physical layout diagram (floor plan) of a NAND-type flash memory on a semiconductor chip using single sided sense amplifiers. FIG. 6 is a floor plan illustrating a NAND-type flash memory on a semiconductor chip using shared sense amplifiers.

In FIG. 5, the semiconductor chip 100 has thereon four planes 500, 501, 502, and 503. Page buffer blocks 550, 551, 552, and 553 store bit line data of the planes 500, 501, 502, and 503, respectively. Each of the buffer blocks may include a sense amplifier circuit for sensing data from each of the planes.

In FIG. 5, the substantial center part of the semiconductor chip 100 in the X direction has a peripheral circuit 530. The peripheral circuit 530 is sandwiched between row decoders 520 (e.g., row decoders 520 are provided at left sides of planes 501 and 503 and row decoders 520 are provided at right sides of plane 500 and 502). The respective row decoders 520 select and drive word lines of corresponding planes 500 to 503, respectively. Specifically, the respective row decoders perform page selection of the respective planes.

The peripheral circuit 530 is also provided at left side in the X direction of the semiconductor chip 100 and left sides of the planes 500 and 502.

Data sensed and stored by the respective buffer blocks is finally output, through a control circuit in the peripheral circuit 530 and an external output transistor circuit, from a pad section 540 to outside. When data lines from the respective page buffer blocks to the control circuit are long, a wiring resistance is increased to cause a problem where a RC delay time is increased due to this wiring resistance and capacity between wirings due to an interlayer insulating film. The increased RC delay time contradicts the demand for a more high-speed data transmission. Thus, a data line desirably has a wide wiring width and a short wiring length.

When a plurality of planes are placed on one semiconductor chip, wiring lengths from a page buffer block and to a pad section are different for every page buffer block depending on a pad section arrangement region and a method for dividing a plane. In this case, every page buffer has a different RC delay time and thus a problem of skew is caused. The term “skew” herein means the length of a temporal difference among a plurality of events that should be simultaneously generated in order to perform a plurality of data transmission processings. Simultaneous data processings must be performed in accordance with a page buffer block having the longest RC delay time, which is a cause of hindering a more high-speed data transmission.

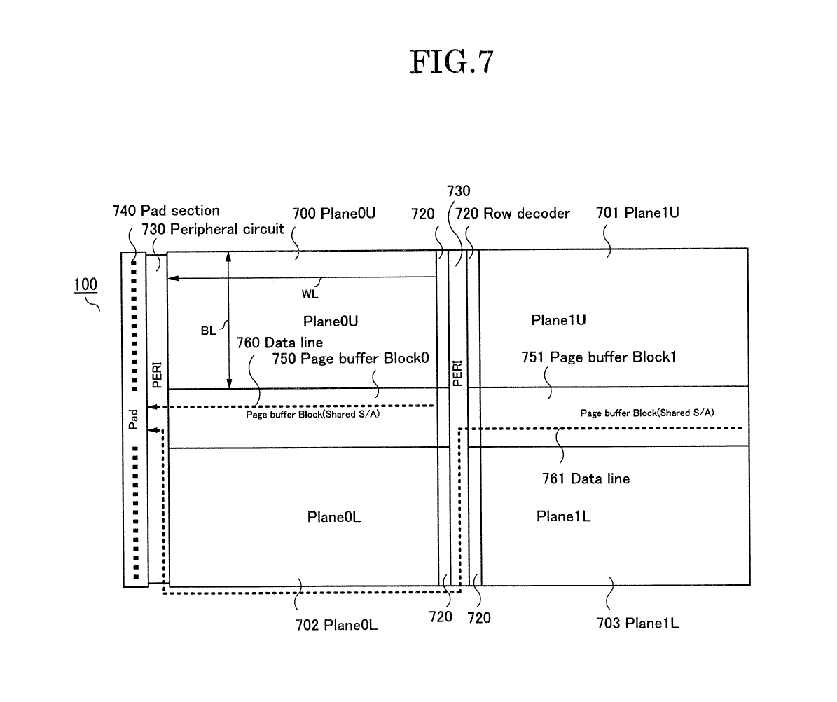

When a page buffer block 751 that is placed at an end on a semiconductor chip and that is far away from a pad section has a data line wired by bypassing a plane OL 702 as shown in FIG. 7, the wiring length is increased, a RC delay time is increased, and a data line of a page buffer block 750 and the data line of the page buffer block 751 have significantly different wiring lengths, causing a problem of skew. Although FIG. 7 uses shared amplifiers as sense amplifiers, the invention is not limited to this and single sided amplifiers also may be used.

Embodiment 1 of the present invention is based on a wiring method as shown in FIG. 5. Data sensed and stored by page buffer blocks 550 and 552 shown in FIG. 5 is output via data lines (dotted line) 560 and 562 to the peripheral circuit 530 and the pad section 540. Data sensed and stored by page buffer blocks 551 and 553 is output via data lines (dotted line) 561 and 563 which are penetrated page buffer blocks 550 and 552 to the peripheral circuit 530 and the pad section 540. This can minimize, in the floor plan in which a pad section is placed on an end on a semiconductor chip, RC delay and can minimize skew. The page buffer blocks 550 and 552 have interconnection in a metal layer. The penetration of data lines may be performed by wiring data lines 561 and 563 from page buffer blocks 551 and 553 to the pad section in the metal layer adjacent to the interconnection of the page buffer blocks 550 and 552 or by wiring the data lines 561 and 563 in different metal layer via an interlayer insulating film. When the wiring in the metal layer adjacent to the interconnection of the page buffer blocks 550 and 552 is performed, a pattern is formed on an identical electrode layer. Thus, the number of processes can be reduced but a shorter wiring width is required. When data lines from the page buffer blocks 551 and 553 are formed on different metal layer via an interlayer insulating film on the other hand, the number of processes is increased but a longer wiring width can be used.

FIG. 6 shows an example of a physical layout (floor plan) illustrating a NAND-type flash memory on a semiconductor chip using shared sense amplifiers. A shared sense amplifier uses one sense amplifier to sense bit line data of two planes in a time division manner. In FIG. 6, a page buffer block 650 including a sense amplifier used shared sense amplifiers senses and stores bit line data of a plane 0U600 and a plane 0L602. By placing sense amplifiers at the center of the plane as shown in FIG. 6, a physical bit line can be halved when compared with a case where single end sense amplifiers are used. This can reduce capacity and resistance of a bit line and a bit line operation can be performed with a higher speed while suppressing an increase of a chip size. The above description shows a comparison for the same plane size. It is noted that, even when the shared sense amplifiers shown in FIG. 6 are used, a problem for a data line length from a page buffer block to a pad section in the case where a pad section is placed at an end of the semiconductor chip 100 has no change as in the case where the single sided sense amplifiers shown in FIG. 5 are used.

### Embodiment 2

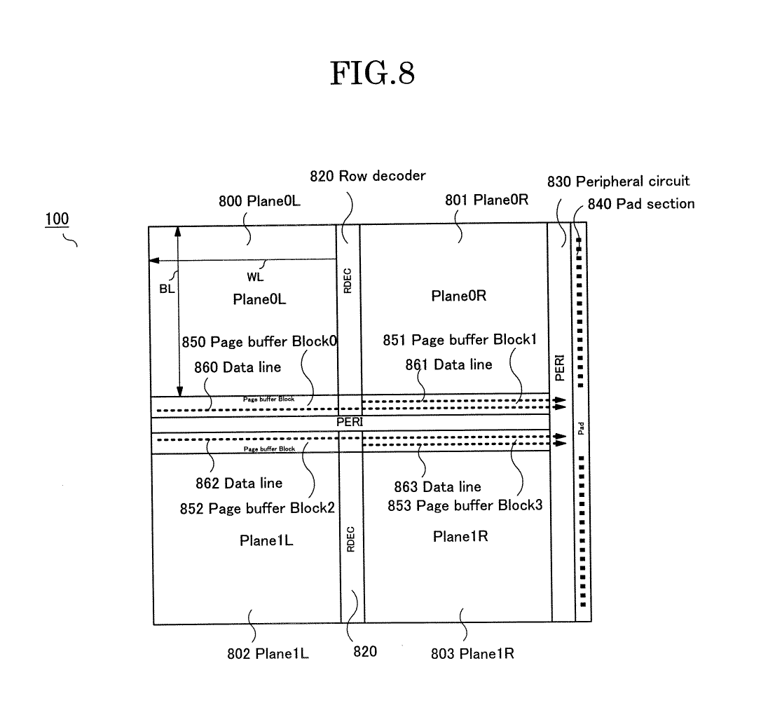

FIG. 8 to FIG. 10 are examples of a floor plan illustrating a nonvolatile semiconductor memory device of Embodiment 2 of the present invention. FIG. 8 shows a physical layout (floor plan) a NAND-type flash memory which has page buffer blocks including sense amplifier circuits used single sided sense amplifiers, placed on a semiconductor chip as in FIG. 5.

The floor plan of the nonvolatile semiconductor memory device according to Embodiment 2 shown in FIG. 8 is different from the floor plan of the nonvolatile semiconductor memory device according to Embodiment 1 shown in FIG. 5 in that the substantial center part of the semiconductor chip does not have a peripheral circuit, row decoders 820 are placed, and the row decoders 820 select a block in a memory cell arrays positioned at the left and right sides thereof and select and drive a word line and a selection gate line respectively.

Data sensed and stored by the page buffer blocks 850 and 852 is output via the data lines (dotted line) 860 and 862 which are penetrated page buffer blocks 851 and 853 to a peripheral circuit 830 and a pad section 840. This can minimize RC delay in the floor plan where a pad section is placed at an end of a semiconductor chip and can minimize skew.

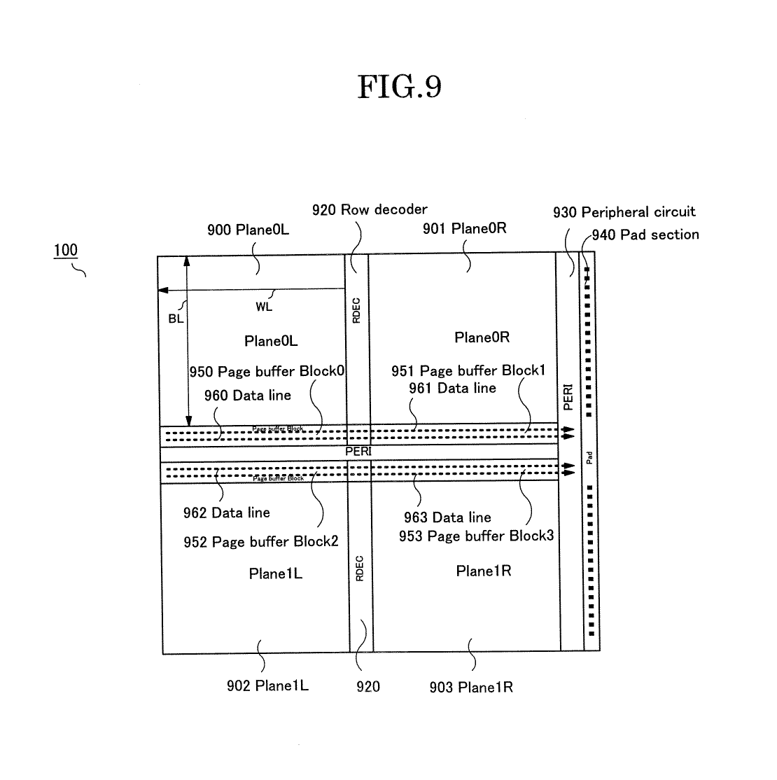

In the floor plan of the nonvolatile semiconductor memory device shown in FIG. 8, data sensed and stored by the respective page buffer blocks 850, 851, 852, and 853 are output via the respective data lines 860, 861, 862, and 863 to the peripheral circuit 830 and the pad section 840. In the floor plan of the nonvolatile semiconductor memory device shown in FIG. 9 on the other hand, data sensed and stored by a page buffer block 950 and a page buffer block 951 are output via a data line 960 and a data line 961 commonly to a peripheral circuit 930 and a pad section 940.

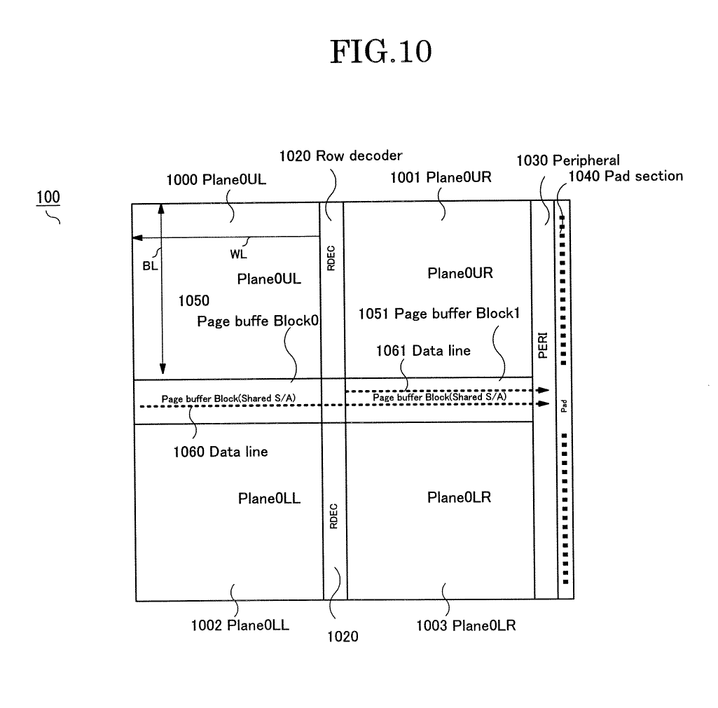

A floor plan of a nonvolatile semiconductor memory device shown in FIG. 10 is a physical layout (floor plan) of a semiconductor chip on a NAND-type flash memory which has page buffer blocks including sense amplifier circuits used shared sense amplifiers as in the floor plan of the nonvolatile semiconductor memory device shown in FIG. 6. A shared sense amplifier senses bit line data of two planes in a time division manner. As in the floor plan of the nonvolatile semiconductor memory device shown in FIG. 6, the floor plan of FIG. 10 can provide a simpler circuit layout on a semiconductor chip and can provide high integration by using shared sense amplifiers.

### Embodiment 3

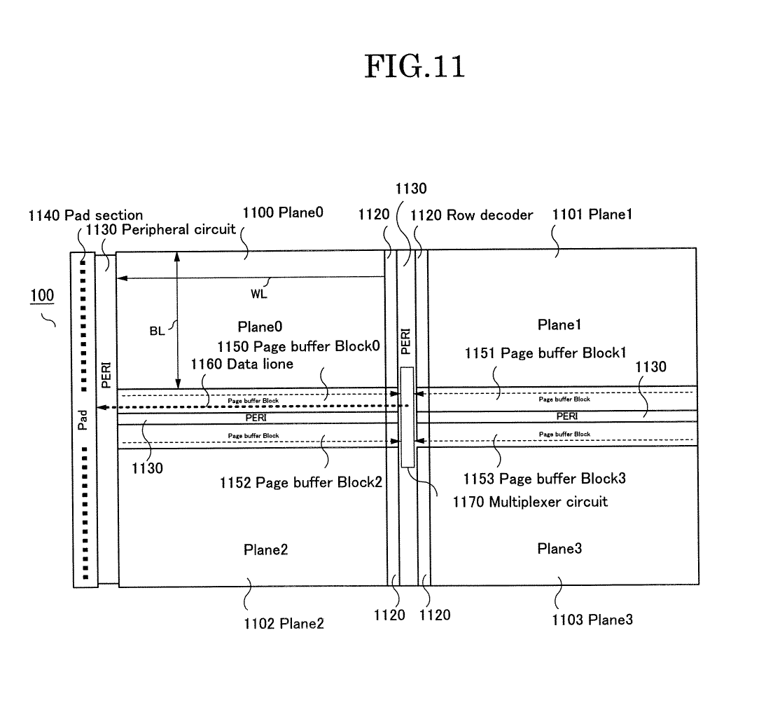

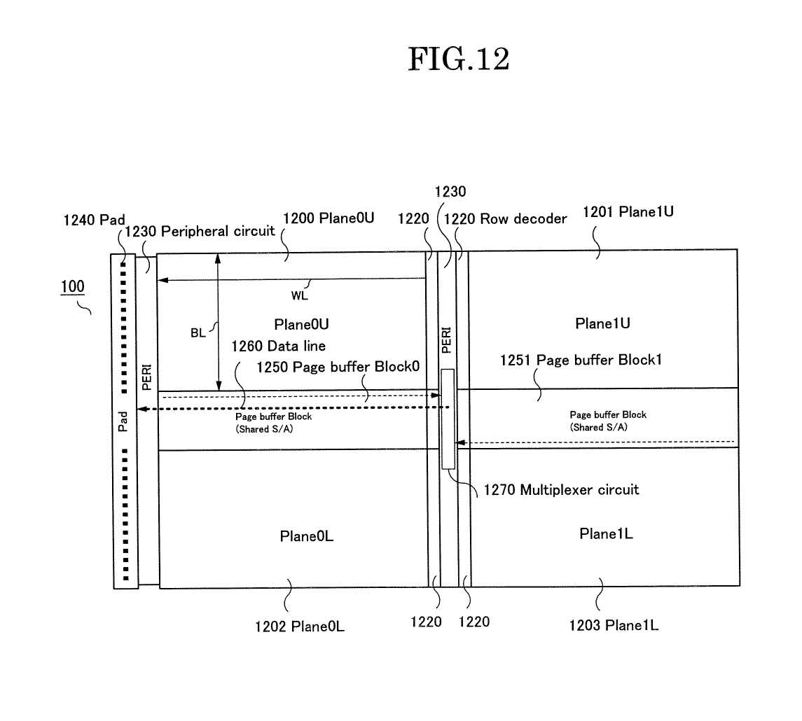

FIG. 11 and FIG. 12 illustrate examples of a floor plan of a nonvolatile semiconductor memory device according to Embodiment 3 of the present invention. FIG. 11 shows an example of a physical layout (floor plan) of a NAND-type flash memory on a semiconductor chip using single sided sense amplifiers. FIG. 12 is an example of a physical layout (floor plan) of a NAND-type flash memory on a semiconductor chip using shared sense amplifiers.

In FIG. 11, the semiconductor chip 100 has thereon four planes 1100, 1101, 1102, and 1103 as in FIG. 5. Page buffer blocks 1150, 1151, 1152, and 1153 stores bit line data of planes 1100, 1101, 1102, and 1103, respectively. Furthermore, each of the page buffer blocks may include a sense amplifier circuit for sensing data from each of the planes.

In FIG. 11, a pad section 1140 is placed at a left end in the X direction of the semiconductor chip 100. A peripheral circuit 1130 is placed between the pad section 1140 and planes 1100 and 1102. At right sides of the planes 1100 and 1102, row decoders 1120 are provided. The row decoders 1120 are also provided at the left side of the planes 1101 and 1103. The respective row decoders select a page in neighboring planes. At the center in the X direction, the peripheral circuit 1130 is placed. This peripheral circuit 1130 includes a multiplexer circuit 1170 at the center in the X direction and at the center in the Y direction.

Embodiment 3 is different from Embodiment 1 and Embodiment 2 in that output data of a page buffer blocks is once collected by the multiplexer circuit 1170 placed at the center part in the X direction of a semiconductor chip. A multiplexer circuit collects a plurality of pieces of output data sent from a page buffer blocks and outputs one piece of data to a data output control circuit and the pad section 1140 placed at the left end in the X direction of the semiconductor chip. The multiplexer circuit may include a sense amplifier circuit or a driving circuit including inverters. The page buffer blocks 1150 and 1152 have interconnection in a metal layer. The penetration of data line may be performed by wiring data line 1160 from the sense amplifier/multiplexer circuit 1170 to the pad section 1140 in the metal layer adjacent to the interconnection of the page buffer blocks 1150 or 1152 or by wiring the data line 1160 in different metal layer via an interlayer insulating film although the data line 1160 is wired in the page buffer block 1150 in FIG. 11.

FIG. 12 shows an example of a physical layout (floor plan) of a NAND-type flash memory on a semiconductor chip which has page buffer blocks including sense amplifier circuits used shared sense amplifiers. A shared sense amplifier senses bit line data of two planes in a time division manner. In FIG. 12, a page buffer block 1250 using shared sense amplifiers senses and stores bit line data of a plane OU 1200 and a plane OL 1202. By placing the sense amplifiers at the center of a plane as shown FIG. 12, a physical bit line length can be halved when compared to a case where single sensed amplifiers are used. This can reduce a bit line capacity and resistance. Thus, a bit line operation can be performed with a higher speed while suppressing an increase of a chip size. The above description shows a comparison for the same plane size.

It is noted that, even when the shared sense amplifiers shown in FIG. 12 are used, the output data of the page buffer blocks 1250 and 1251 is once collected by a multiplexer circuit 1270 placed at the center in the X direction of the semiconductor chip. The multiplexer circuit collects a plurality of pieces of output data sent from the page buffer blocks and outputs one piece of data to a data output control circuit and the pad section 1240 placed at the left end in the X direction of the semiconductor chip

In Embodiment 3, the respective page buffer blocks sense and store bit line data of the respective planes and output data of the respective page buffer blocks is collected by a multiplexer circuit placed at the center in the X direction on the semiconductor chip. A data line length from the page buffer blocks and to the multiplexer circuit is equal without being different for the respective page buffer blocks. Thus, skew of the data transfer time can be avoided.

The above description has described, with regards to the embodiment in which a data transmission delay is minimized, skew is minimized, and high integration is realized, a method for placing or wiring circuit elements or data lines on a two-dimensional plane on a semiconductor chip. The above-described embodiments of the present invention are based on an assumption that a pad section is placed at an end on a semiconductor chip. Embodiment 1 of the present invention has described the method for minimizing a wiring length of a reading data line by penetrating a data line from a page buffer block far away to a pad section into a page buffer block close to the pad section to wire the data line to the pad section. Embodiment 3 of the present invention has described the method for avoiding skew of a data transfer time by placing a multiplexer circuit at the center in the X direction of the semiconductor chip so that data from the respective page buffer blocks is once collected by multiplexer circuit to provide an equal data line length.

### Embodiment 4

Next, Embodiment 4 of the present invention will be described. Embodiment 4 of the present invention is different from Embodiments 1 to 3 in that semiconductor chips are layered to provide a multilayer structure.

The method for placing circuit elements on a two-dimensional plane on a semiconductor chip to wire the circuit elements has limitation in the reduction of a packaging area. When a wiring width is miniaturized, wiring resistance cannot be ignored. Thus, RC delay is caused by a capacity component of an interlayer insulating film to hinder high-speed transmission.

It is expected that demands for a higher memory capacity, a more high-speed data processing speed, and higher integration will be further increased. Thus, Embodiment 4 provides a means that not only places a circuit placement region and a wiring region in one layer but also provides a circuit placement region and a wiring region among many layers so that a wide region is secured in one layer to provide a margin to a wiring width. This means of Embodiment 4 uses a technique (System in Package) according to which a plurality of semiconductor chips are layered and packaged in a package in a three-dimensional direction and the respective layers are connected by a penetration electrode.

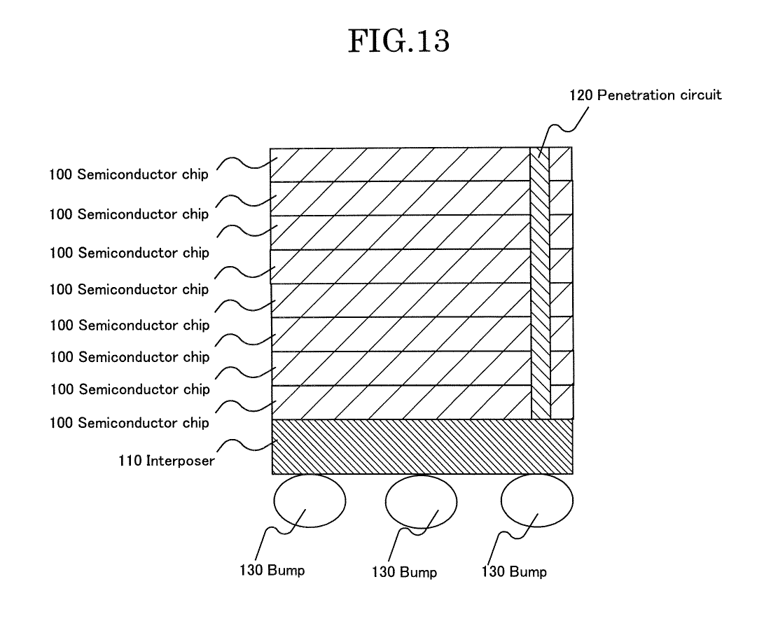

FIG. 13 illustrates an example of the structure of layered chips of a nonvolatile semiconductor memory device according to Embodiment 4 of the present invention. Three-dimensional packaging techniques for sealing chips of a multilayer structure in a package and connecting the respective layers include a penetration electrode 120. The penetration electrode 120 is formed by providing a through hole in a bare chip, filling the through hole with a conductive material such as Cu and forming bump-like conductive materials on the surface simultaneously or thereafter. Chips of the respective layers are joined by bonding resin. The through hole is electrically connected by joining the bump-like protruding electrodes at the surface. Since the wiring is provided in a vertical direction in the chip, a space between the semiconductor chips 100 or a space between the semiconductor chip 100 and the interposer 110 can be connected with the minimum distance and in a flexible manner.

In the case of a multilayer chip, a conventional wire bonding method requires a bypass in the interior, thus suppressing a high-speed operation. When the number of wirings bypassed in a package is increased, a possibility of short-circuiting is increased even when a wire bonding is used. Thus, a multilayer structure by a penetration electrode that does not depend on a wire bonding is desirable.

An external terminal and an electrode of a semiconductor chip are connected via the projection-like connection electrode bump 130 and the interposer 110 for directly joining an electrode. The respective semiconductor chips 100 of a layered structure have substantially the same layout. Alternatively, the respective chips (respective layers) also may have a two-plane structure or may have a 4×n-plane structure. The respective chips are connected by the penetration electrode 120. When data is input/output to/from an eternal part with respect to each layer (with respect to chips of each layer), each layer requires a means for selection and non-selection. In Embodiment 4, each layer includes a chip enable terminal. By a penetration electrode, all layers are connected with chip enable terminals of the respective layers. However, in a layer to be selected by a certain chip enable terminal, wiring in the chip may be performed and a not-to-be-selected layer may not be connected (NC) (not shown).

We claim:

1. A nonvolatile semiconductor memory device comprising:
a first memory cell array including a plurality of electrically reprogrammable and erasable nonvolatile memory cells formed in a first area of a semiconductor substrate;
a second memory cell array including a plurality of electrically reprogrammable and erasable nonvolatile memory cells formed in second area different from said first area of said semiconductor substrate, said first and second memory cell arrays being arranged in a first direction;
a first page buffer block for storing data from said first memory cell array, said first page buffer block being arranged in said first memory cell array along a first direction;
a second page buffer block for storing data from said second memory cell array, said second page buffer block being arranged in said second memory cell array along said first direction;
a pad section for inputting data to and outputting data from said first memory cell array and said second memory cell array, said pad section having a plurality of pads arranged in an end of a semiconductor chip along a second direction perpendicular to said first direction;
a first data line for supplying data from said first memory cell array to said pad section, said first data line being arranged in said first memory cell array along said first direction; and
a second data line for supplying data from said second memory cell array to said pad section, said second data line being arranged in said second memory cell array along said first direction over said first page buffer block.

2. The nonvolatile semiconductor memory device according to claim 1 further comprising:
a first row decoder for selecting word lines in said first memory cell array, said first row decoder being arranged between said first memory cell array and said second memory cell array along said second direction; and
a second row decoder for selecting word lines in said second memory cell array, said second row decoder being arranged between said first memory cell array and said second memory cell array along said second direction.

3. The nonvolatile semiconductor memory device according to claim 2 further comprising:
a first peripheral circuit including a circuit for driving said first and second row decoders arranged between said first row decoder and said second row decoder.

4. The nonvolatile semiconductor memory device according to claim 1 further comprising:
a second peripheral circuit including a circuit for driving said first page buffer block arranged in said first memory cell array along said first direction; and
a third peripheral circuit including a circuit for driving said second page buffer block arranged in said second memory cell array along said first direction.

5. The nonvolatile semiconductor memory device according to claim 1 further comprising:
a fourth peripheral circuit including a control circuit arranged between said first memory cell array and said pad section along said second direction.

6. The nonvolatile semiconductor memory device according to claim 1 wherein:
said first page buffer has an interconnection arranged in a first level metal layer; and
said second data line is arranged in said first level metal layer and in adjacent to said interconnection.

7. The nonvolatile semiconductor memory device according to claim 1 wherein:
said first page buffer has an interconnection arranged in a first level metal layer; and
said second data line is arranged in a second level metal layer being different from said first level metal layer, an interlayer insulating film being arranged between said first level metal layer and said second level metal layer.

8. The nonvolatile semiconductor memory device according to claim 1 further comprising:
a row decoder being arranged between said first memory cell array and said second memory cell array, said row decoder selecting word lines in said first memory cell array and second memory cell array.

9. The nonvolatile semiconductor memory device according to claim 8 wherein:
said first page buffer has an interconnection arranged in a first level metal layer; and
said second data line is arranged in said first level metal layer and in adjacent to interconnection.

10. The nonvolatile semiconductor memory device according to claim 8 wherein:
said first page buffer has an interconnection arranged in a first level metal layer; and
said second data line is arranged in a second level metal layer being different from said first level metal layer, an interlayer insulating film being arranged between said first level metal layer and said second level metal layer.

11. The nonvolatile semiconductor memory device according to claim 8 further comprising:
a fifth peripheral circuit including circuits for driving said first and second page buffer blocks and said row decoder arranged in said first and second memory cell arrays along said first direction; and
a sixth peripheral circuit including a control circuit arranged between said first memory cell array and said pad section along said second direction.

12. The nonvolatile semiconductor memory device according to claim 1 wherein:
said electrically reprogrammable and erasable nonvolatile memory cells are arranged to be NAND type.

13. A nonvolatile semiconductor memory device comprising:
a first memory cell array including a plurality of electrically reprogrammable and erasable nonvolatile memory cells formed in a first area of a semiconductor substrate;
a second memory cell array including a plurality of electrically reprogrammable and erasable nonvolatile memory cells formed in second area different from said first area of said semiconductor substrate, said first and second memory cell arrays being arranged in a first direction;
a first page buffer block for storing data from said first memory cell array, said first page buffer block being arranged in said first memory cell array along a first direction;
a second page buffer block for storing data from said second memory cell array, said second page buffer block being arranged in said second memory cell array along said first direction;
a pad section for inputting data to and outputting data from said first memory cell array and said second memory cell array, said pad section having a plurality of pads arranged in an end of a semiconductor chip along a second direction perpendicular to said first direction;
a first peripheral circuit including data collect circuit for collecting data from said first and second page buffer blocks and outputting collected data to said pad section, said first peripheral circuit being arranged between said first memory cell array and said second memory cell array along said second direction;
a second peripheral circuit including a control circuit arranged between said first memory cell array and said pad section along said second direction; and
a data line for supplying data from said data collect circuit to said second peripheral circuit and said pad section, said data line being arranged in said first memory cell array along said first direction over said first page buffer block.

14. The nonvolatile semiconductor memory device according to claim 13 further comprising:
a first row decoder for selecting word lines in said first memory cell array, said first row decoder being arranged between said first memory cell array and said first peripheral circuit along said second direction; and
a second row decoder for selecting word lines in said second memory cell array, said second row decoder being arranged between said second memory cell array and said first peripheral circuit along said second direction.

15. The nonvolatile semiconductor memory device according to claim 13 wherein:
said first page buffer has an interconnection arranged in a first level metal layer; and
said data line is arranged in said first level metal layer and in adjacent to said interconnection.

16. The nonvolatile semiconductor memory device according to claim 13 wherein:
said first page buffer has an interconnection arranged in a first level metal layer; and
said data line is arranged in a second level metal layer being different from said first level metal layer, an interlayer insulating film being arranged between said first level metal layer and said second level metal layer.

17. The nonvolatile semiconductor memory device according to claim 13 wherein:
said electrically reprogrammable and erasable nonvolatile memory cells are arranged to be NAND type.

18. A semiconductor device comprising:
a plurality of nonvolatile semiconductor memory devices according to claim 1 or claim 13, said plurality of nonvolatile semiconductor memory devices being stacked and being electrically connected via a through hole wiring formed in respective semiconductor substrates of said plurality of nonvolatile semiconductor memory devices.

19. The semiconductor device according to claim 18 further comprising:
an interposer attached and arranged below said plurality of nonvolatile semiconductor memory devices which are stacked: and
a plurality of electrodes formed on said interposer, each of said plurality of electrodes being connected to respective one of plural pads formed in said plurality of nonvolatile semiconductor memory devices respectively.

20. The semiconductor device according to claim 18 wherein:
said plurality of nonvolatile semiconductor memory devices is NAND type.
